(19) United States
(12) Patent Application Publication
(10) Pub. No.: US 2010/0230741 A1
(43) Pub. Date: Sep. 16, 2010

(54) SEMICONDUCTOR DEVICES WITH AN AIR GAP IN TRENCH ISOLATION DIELECTRIC

(75) Inventors: Jongwan Choi, Suwon-si (KR); Eunkee Hong, Sungnam-shi (KR); Bo-Young Lee, Hwaseong-si (KR); Tae-Jong Han, Jeonju-si (KR); Juseon Goo, Suwon-si (KR); Kyungmun Byun, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/711,033

(22) Filed: Feb. 23, 2010

(30) Foreign Application Priority Data
Mar. 12, 2009 (KR) 10-2009-0021321

(51) Int. Cl. H01L 29/792; H01L 29/06

(52) U.S. Cl. 257/324; 257/506; 257/E29.309; 257/E29.02

(57) ABSTRACT

A tunnel insulating layer and a charge storage layer are sequentially stacked on a substrate. A recess region penetrates the charge storage layer, the tunnel insulating layer and a portion of the substrate. The recess region is defined by a bottom surface and a side surface extending from the bottom surface. A first dielectric pattern includes a bottom portion covering the bottom surface and inner walls extending from the bottom portion and covering a portion of the side surface of the recess region. A second dielectric pattern is in the recess region between the inner walls of the first dielectric pattern, and the second dielectric pattern enclosing an air gap. The air gap that is enclosed by the second dielectric pattern may extend through a major portion of the second dielectric pattern in a direction away from the bottom surface of the recess region.

### CROSS-REFERENCE TO RELATED APPLICATIONS

This U.S. non-provisional patent application claims priority under 35 U.S.C. §119 of Korean Patent Application No, 10-2009-0021321, filed on Mar. 12, 2009, the entire contents of which are hereby incorporated by reference.

### BACKGROUND

The inventive concepts relate to semiconductor devices and, more specifically, relates to nonvolatile memory devices.

Nonvolatile memory devices can retain their stored data while their power supplies are interrupted. Depending upon their configuration, nonvolatile memory devices may be categorized into two types, namely, a NOR-type flash memory device (hereinafter referred to as “NOR flash memory device”) and a NAND-type flash memory device (hereinafter referred to as “NAND flash memory device”).

Programming a NAND flash memory device may include applying a predetermined voltage, e.g., 0V, to a selected bit line and applying a power supply voltage (Vcc), e.g., 1.8V˜3.3V, to a gate of a string select transistor. Accordingly, a channel voltage of a cell transistor connected to the selected bit line becomes 0V. A program voltage (Vpgm) is applied to a selected word line to tunnel electrons into the selected cell transistors through Fowler-Nordheim (FN) tunneling. A self-boosting method may be employed to prevent programming of a cell transistor connected to the selected word line and an unselected bit line. A self-boosting method may include applying a voltage of 0V to a ground select transistor to cut off a ground path. To function as a program inhibiting voltage, a power supply voltage (Vcc) may be applied to gates of unselected bit lines and unselected string select transistors. A program voltage (Vpgm) may be applied to a selected word line and a pass voltage (Vpass) may be applied to unselected word lines to boost a channel voltage of an unselected cell transistor.

### SUMMARY

In accordance with some embodiments of the present invention, a tunnel insulating layer and a charge storage layer are sequentially stacked on a substrate. A recess region penetrates the charge storage layer, the tunnel insulating layer and a portion of the substrate. The recess region is defined by a bottom surface and a side surface extending from the bottom surface. A first dielectric pattern includes a bottom portion covering the bottom surface and inner walls extending from the bottom portion and covering a portion of the side surface of the recess region. A second dielectric pattern is in the recess region between the inner walls of the first dielectric pattern, and the second dielectric pattern enclosing an air gap.

In some further embodiments, the air gap that is enclosed by the second dielectric pattern may extend through a major portion of the second dielectric pattern in a direction away from the bottom surface of the recess region. The air gap may extend through a central portion of the second dielectric pattern. The air gap may extends along at least one third of a length of the recess region.

In some further embodiments, the semiconductor device further comprises a third dielectric pattern that is between the bottom portion of the first dielectric pattern and the second dielectric pattern. The third dielectric pattern is disposed between the inner walls of the first dielectric pattern. The first, the second, and the third dielectric pattern fill the recess region to form a device isolation structure defining an active region on the substrate. A top surface of the first dielectric pattern may directly contact the second dielectric pattern in the recess region, and the inner wall of the first dielectric pattern may directly contact the second and the third dielectric patterns.

In some further embodiments, the recess region is defined by a first region having a first width, and a second region having a second width that corresponds to a distance between the inner sidewalls of the first dielectric pattern. The second width is smaller than the first width. The first region is defined by a region between the top surface of the inner wall of the first dielectric pattern and a top surface of the second dielectric pattern, and the second region is defined by a region between the top surface of the inner wall of the first dielectric pattern and a top surface of the third dielectric pattern.

In some further embodiments, the air gap enclosed by the second dielectric pattern is disposed within the second region between adjacent portions of the tunnel insulating layer that are separated by the recess region.

In some further embodiments, the inner wall of the first dielectric pattern may cover side surfaces of the tunnel insulating layer that are separated by the recess region. The first dielectric pattern may have a lower dielectric constant than the second and the third dielectric patterns. The charge storage layer may comprise a charge trap layer.

In some further embodiments, a fourth dielectric pattern may cover the top surface and an upper portion of the inner wall of the first dielectric pattern and narrow a width of an upper portion of the recess region to cause formation of the air gap during formation of the second dielectric pattern. The fourth dielectric pattern may comprise a material having poorer step coverage than the first, the second, and the third dielectric patterns.

In some further embodiments, the fourth dielectric pattern may extend an equal distance away from the upper portion of the inner wall of the first dielectric pattern to narrow the width of an upper portion of the recess region. The air gap within the second dielectric pattern may be between the fourth dielectric pattern and extend downward through a major portion of the second dielectric pattern. The air gap within the second dielectric pattern may be about equal distance from the fourth dielectric pattern. A top surface of the air gap within the second dielectric pattern may be below a top surface of the fourth dielectric pattern and between the fourth dielectric pattern.

In some further embodiments, the semiconductor device further includes a plurality of the recess regions with the first and second dielectric patterns residing therein. Each of the second dielectric patterns encloses a substantially similar size air gap within that dielectric pattern.

One or more of these embodiments may provide improved channel-boosting efficiency for semiconductor devices.

### BRIEF DESCRIPTION OF THE DRAWINGS

The accompanying drawings are included to provide a further understanding of the inventive concepts, and are incorporated in and constitute a part of this specification. The drawings illustrate exemplary embodiments of the inventive concepts and, together with the description, serve to explain principles of the inventive concepts. In the figures:

FIG. 1 is a top plan view of a semiconductor device according to some exemplary embodiments;

FIG. 2A is a cross-sectional view taken along the dotted lines A-A′ and B-B′ in FIG. 1, which illustrates a semiconductor device according to some exemplary embodiments;

FIG. 2B is a cross-sectional view taken along the dotted lines A-A′ and B-B′ in FIG. 1, which illustrates a semiconductor device according to some other exemplary embodiments;

FIGS. 3A through 3J are cross-sectional views, which illustrate a method of fabricating a semiconductor device according to some exemplary embodiments;

FIGS. 4A through 4C are cross-sectional views, which illustrate a method of fabricating a semiconductor device according to some other exemplary embodiments;

FIG. 5 is a top plan view of a semiconductor device according to some modified exemplary embodiments;

FIG. 6 is a cross-sectional view taken along the dotted lines A-A′ and C-C′ in FIG. 5, which illustrates a semiconductor device according to some other modified exemplary embodiments;

FIGS. 7A through 7D are cross-sectional views, which illustrate a method of fabricating a semiconductor device according to some modified exemplary embodiments;

FIG. 8 is a block diagram, which illustrates a electronic system employing a semiconductor device according to some exemplary embodiments; and

FIG. 9 is a block diagram, which illustrates a memory card employing a semiconductor device according to some exemplary embodiments.

### DETAILED DESCRIPTION OF THE EMBODIMENTS

The present invention now will be described more fully hereinafter with reference to the accompanying drawings, in which various embodiments are shown. However, this invention should not be construed as limited to the embodiments set forth herein. Rather, these embodiments are provided so that this disclosure will be thorough and complete, and will fully convey the scope of the invention to those skilled in the art. In the drawings, the relative sizes of regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element is referred to as being “on,” “contacted,” “connected,” “coupled” or “responsive” to another element (or variations thereof), it can be directly on, contacted, connected, coupled or responsive to the other element, or intervening elements may be present. In contrast, when an element is referred to as being “directly on,” “directly contacted,” “directly connected,” “directly coupled” or “directly responsive” to another element (or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “bottom,” “top,” “horizontal,” “lateral” and “vertical” (or variations thereof) may be used herein to describe one element's relationship to another element as illustrated in the Figures. It will be understood that relative terms are intended to encompass different orientations of the device in addition to the orientation depicted in the Figures. For example, the terms “horizontal” and “vertical” are used to refer to two generally orthogonal directions, but do not imply a specific orientation.

Embodiments of the present invention are described herein with reference to cross section and perspective illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

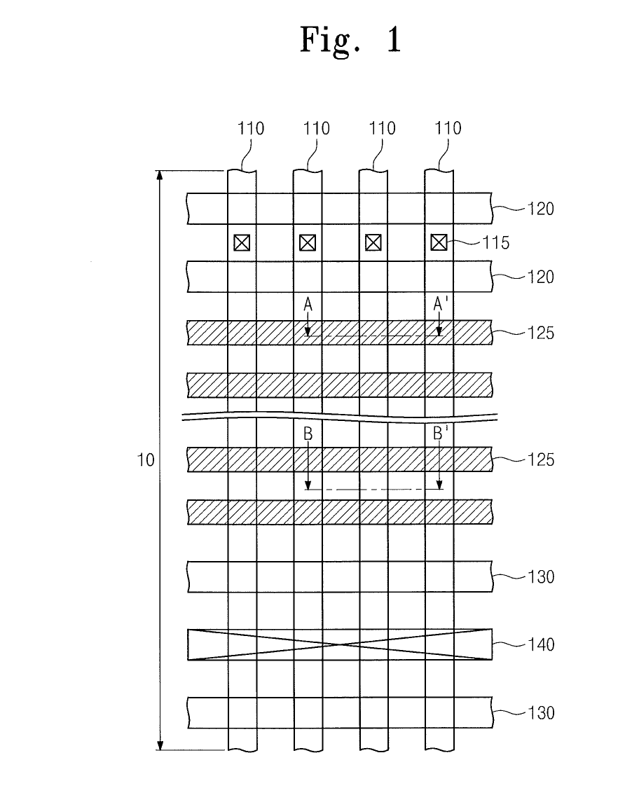

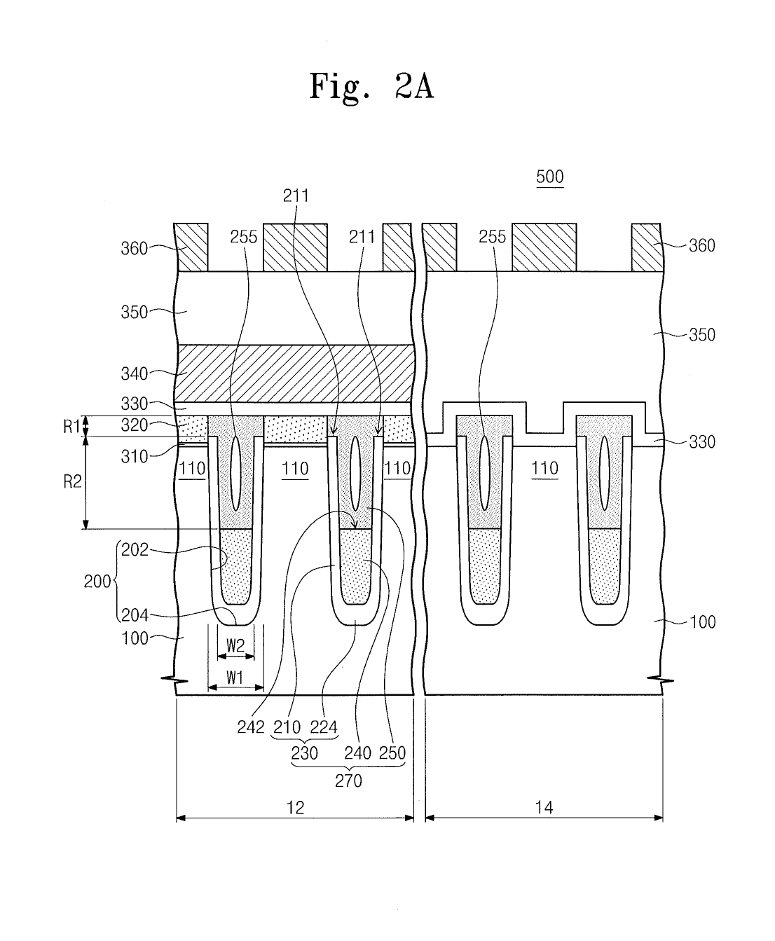

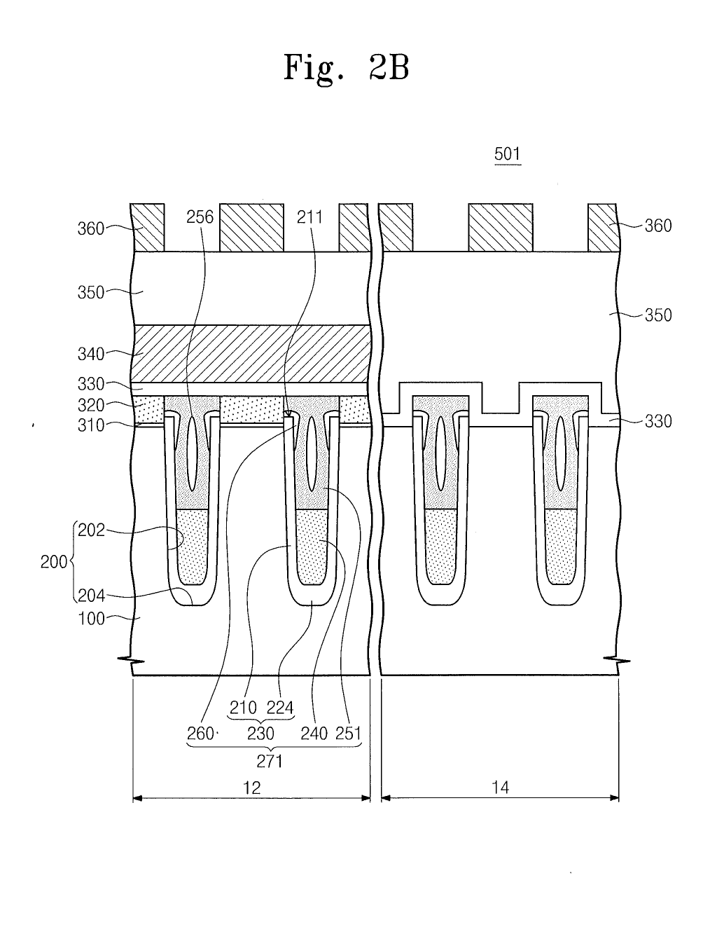

FIG. 1 is a top plan view of a semiconductor device according to some exemplary embodiments. FIG. 2A is a cross-sectional view along the dotted lines A-A′ and B-B′ in FIG. 1, which illustrates a semiconductor device according to some exemplary embodiments. A first cross-sectional area 12 may be a cross-sectional area taken along the dotted line A-A′ in FIG. 1, and a second cross-sectional area 14 may be a cross-sectional area taken along the dotted line B-B′ in FIG. 1.

Referring FIG. 1 and FIG. 2A, a semiconductor device 500 according to some exemplary embodiments may be, for instance, a NAND flash memory device. The semiconductor device 500 may include a substrate 100 including a cell region 10. The cell region 10 may include a cell array comprising a plurality of cell strings. The plurality of cell strings include a ground select line 130, a string select line 120 and a word line 125 disposed between the ground select line 130 and the string select line 120. A common source line 140 is disposed between the ground select lines 130 adjacent to each other. The common source line 140 electrically connects source regions (not shown) of the ground select line 130. A bit line contact 115 is provided between the string select lines 120 adjacent to each other. A bit line 360 is disposed on the word line 125.

A device isolation structure 270 may define an active region 110 on the substrate 100. The device isolation structure 270 may protrude from the substrate 100. A tunnel insulating layer 310 and a charge storage layer 320 may be sequentially stacked on the active region 110 of the first cross-sectional area 12. A top surface of the charge storage layer 320 may form a coplanar surface with the top surface, for instance a protruding surface, of the device isolation structure 270 of the first cross-sectional area 12. A blocking dielectric layer 330 may be disposed on the device isolation structure 270 and on the charge storage layer 320 of the first cross-sectional area 12. The blocking dielectric layer 330 may uniformly cover the top surface of the device isolation structure 270 and the top surface of the charge storage layer 320 of the first cross-sectional area 12. The blocking dielectric layer 330 may uniformly cover the protruding surface of the device isolation structure 270 and the active region 110 of the second cross-sectional area 14. A control gate electrode 340 forming the word line 125 may cover the blocking dielectric layer 330 of the first cross-sectional area 12. An interlayer dielectric layer 350 may cover the control gate electrode 340 of the first cross-sectional area 12 and the blocking dielectric layer 330 of the second cross-sectional area 14. The bit lines 360 may be disposed on the interlayer dielectric layer 350.

According to some exemplary embodiments, the device isolation structure 270 may include a first dielectric pattern 230, a second dielectric pattern 240, and a third dielectric pattern 250 having an air gap 255. The device isolation structure 270 may fill a recess region 200 penetrating the charge storage layer 320, the tunnel insulating layer 310 and a portion of the substrate 100. A recess region 200 may be defined by a side surface 202 and a bottom surface 204. The side surface 202 of the recess region 200 may form a coplanar surface with the side surface of the charge storage layer 320, the side surface of the tunnel insulating layer 310, and the side surface of the trench formed in the substrate 100. The side surface 202 of the recess region 200 may have a right angle or an obtuse angle. The bottom surface 204 of the recess region 200 may be the bottom surface of the trench. A distance between opposite side surfaces 202 across the recess region 200 may be about a first width W1 along at least a major portion thereof. The first width W1 may range, for instance, from 20 to 90 nm.

The first dielectric pattern 230 may include an inner wall 210 and a bottom portion 224. The bottom portion 224 may cover the bottom surface 204 of the recess region. The inner wall 210 may be connected to the bottom portion 224, and may extend integrally therefrom, and cover the recess region 200 along a portion of the side surface 202 of the recess region 200. The inner wall 210 may include a top surface 211 adjoining the third dielectric pattern 250 and a side surface adjoining second and the third dielectric patterns 240 and 250. The top surface 211 of the inner wall 210 may be separated from a top surface of the third dielectric pattern 250. The inner wall 210 may cover the side surface of the tunnel insulating layer 310. The top surface 211 of the inner wall 210 may be located within a first range of distances from another defined surface, such as between first and second defined distances. The first distance may be a distance of at most 300 Å upward from the surface of the substrate 100. The second distance may be a distance of at least 500 Å downward from the surface of the substrate 100. The upward direction may be a direction extending vertically towards the blocking dielectric layer 330 from the substrate 100, and the downward direction may be a direction opposite to the upward direction. The thickness of the inner wall 210 may be 35% or less of the first width W1. The first dielectric pattern 230 may include a layer having a lower dielectric constant than those of the second dielectric pattern 240 and the third dielectric pattern 250. The first dielectric pattern 230 may be made of, for instance, middle temperature oxide. The first dielectric pattern 230 may include a porous thin film, e.g., a silicon oxide film containing carbon and/or hydrogen.

The second dielectric pattern 240 may cover the bottom portion 224 of the first dielectric pattern 230 and may have a planar top surface 242. The top surface 242 of the second dielectric pattern 240 may be located within a second range that may be, for example, at most 500 Å downward from the surface of the substrate 100. The second dielectric pattern 240 may include one selected from the group consisting of, for instance, Spin-On-Glass (SOG), Flowable-Oxide (FOX), Boron-Phosphorous Silicate Glass (BPSG), doped oxide such as germanium doped oxide, and combinations thereof.

The recess region 200 may comprise a first region R1 and a second region R2. The first region R1 may have a first width W1. The first width W1 may be a distance between opposite side surfaces 202 across the recess region 200. The first region R1 may comprise a region between the top surface 211 of the inner wall 210 of the first dielectric pattern 230 and the top surface of the third dielectric pattern 250. The second region R2 may have a second width W2. The second width W2 may be a distance between opposite side surfaces of the inner wall 210. The second region R2 may comprise a region between the top surface 211 of the inner wall 210 and the top surface 242 of the second dielectric pattern 240.

The third dielectric pattern 250 may fill in the first region R1 and the second region R2 of the recess region 200. The air gap 255 may be disposed in the third dielectric pattern 250 in the second region R2, between the active regions 110 neighboring the tunnel insulating layers 310. The air gap 255 may extend in a direction toward the surface of the substrate 100 through a major portion of the third dielectric pattern 250 in the second region R2, and may be completely enclosed by the third dielectric pattern 250. The air gap 255 may extend through a central portion and along a major portion of the second region R2 in a direction toward the surface of the substrate 100. The third dielectric pattern 250 may include, for instance, a high-density plasma (HDP) oxide layer. The air gap 255 that is enclosed by the third dielectric pattern 250 may extend along at least one third of a length of the recess region 200.

According to some exemplary embodiments, the device isolation structure 270 includes the air gap 255, which has a small dielectric constant. The small dielectric constant of the air gap 255 may decrease channel coupling resulting from decrease in critical dimension of the active region 110 and the device isolation region defining the active regions 110. Moreover, according to some exemplary embodiments, the device isolation structure 270 may have a uniformly formed air gap 255 by adjusting the location of the top surface 211 of the inner wall 210 of the first dielectric pattern 230 and the top surface 242 of the second dielectric pattern 240. The air gap 255 may be disposed between the active regions 110 neighboring the tunnel insulating layers 310 to further decrease the channel coupling and maybe without degrading the uniformity of the device isolation structure 270 formed in the recess region 200.

As a result, a voltage applied to the channel of the unselected cell transistor during a program operation of a NAND flash memory device may rise with decrease of channel coupling to improve channel boosting efficiency. Accordingly, channel voltage distribution may also be improved.

FIG. 2B is a cross-sectional view along the dotted lines A-A′ and B-B′ in FIG. 1, which illustrates a semiconductor device according to some other exemplary embodiments. The structure of FIG. 2B is similar to the structure of FIG. 2A and, accordingly, duplicate technical features will be briefly explained or not be explained for brevity of this description.

Referring FIG. 2B, a device isolation structure 271 according the other exemplary embodiments may include a first dielectric pattern 230, a second dielectric pattern 240, a third dielectric pattern 251 having an air gap 256, and a fourth dielectric pattern 260.

The fourth dielectric pattern 260 may cover a top surface 211 of an inner wall 210 of the first dielectric pattern 230 and a side surface connected and adjacent to the top surface 211. The fourth dielectric pattern 260 may be disposed at the boundary between the first region and the second region of FIG. 2A. Residues (not shown) of the fourth dielectric pattern 260 may remain on the second dielectric pattern 240. The fourth dielectric pattern 260 may include a layer having poorer step coverage than those of the first, the second, and the third dielectric patterns 230, 240, and 250. The fourth dielectric pattern 260 may be made of, for instance, Plasma Enhanced Oxide (PEOX).

The fourth dielectric pattern may extend an equal distance away from the upper portion of the inner wall 210 of the first dielectric pattern 230 to narrow the width of an upper portion of the recess region 201. The air gap 256 within the second dielectric pattern 251 may be between the fourth dielectric pattern 260 and extend downward through a major portion of the second dielectric pattern 251. The air gap 256 within the second dielectric pattern 251 may be about equal distance from the fourth dielectric pattern 260. A top surface of the air gap 256 within the second dielectric pattern 251 may below a top surface of the fourth dielectric pattern 260.

According to some other exemplary embodiments, a semiconductor device 501 further including the fourth dielectric pattern 260 may be provided with a device isolation structure 271 having an air gap 256 that is more readily formed by the presence of the fourth dielectric pattern 260. A method of forming the air gap 256 will be described in detail below.

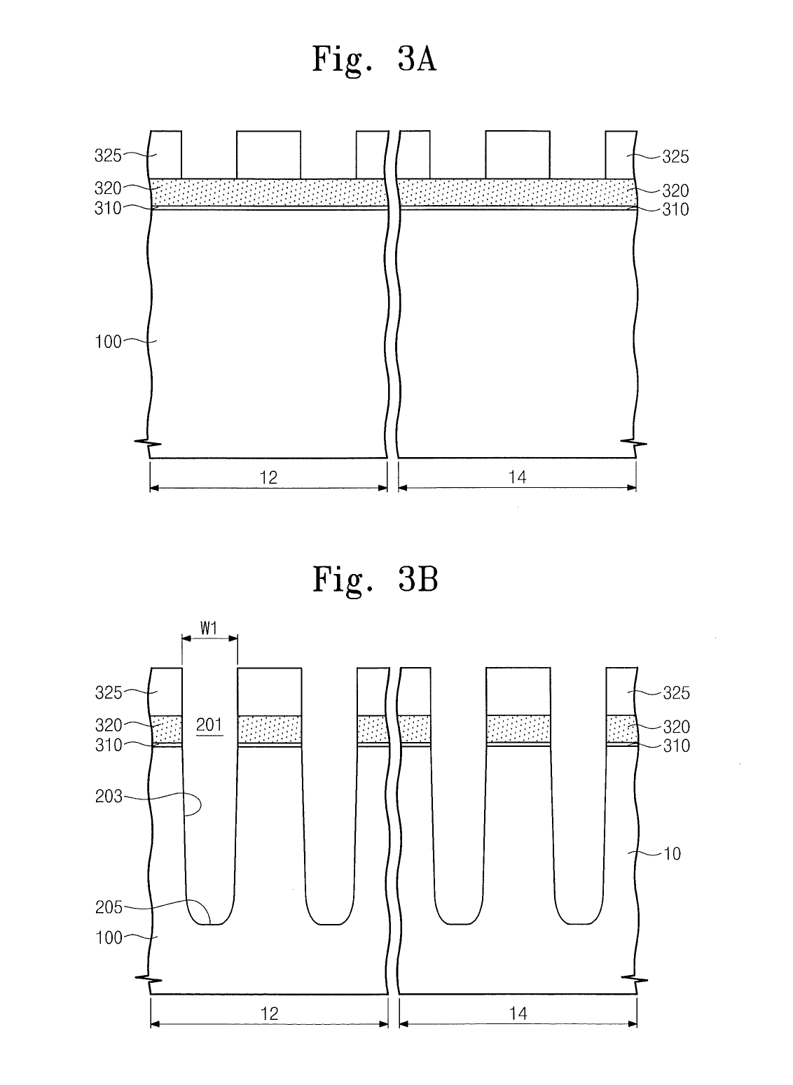

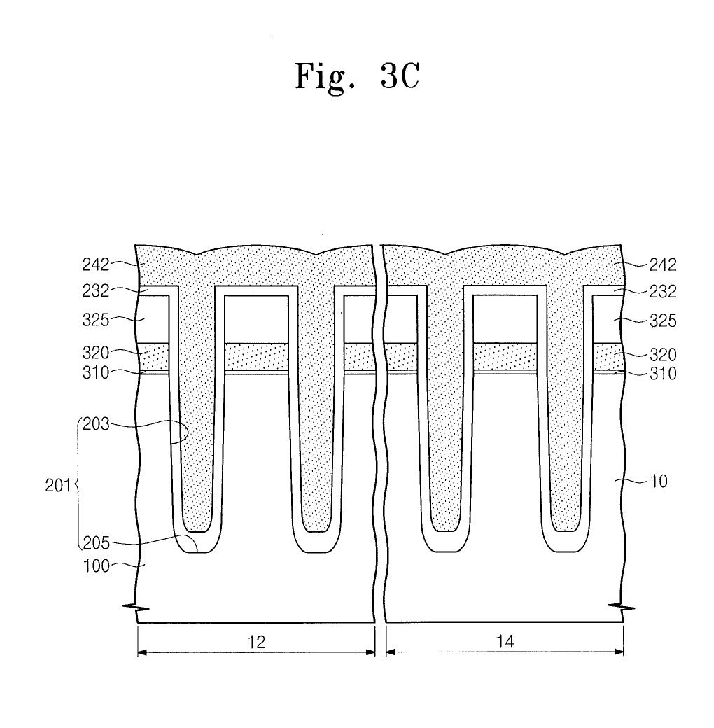

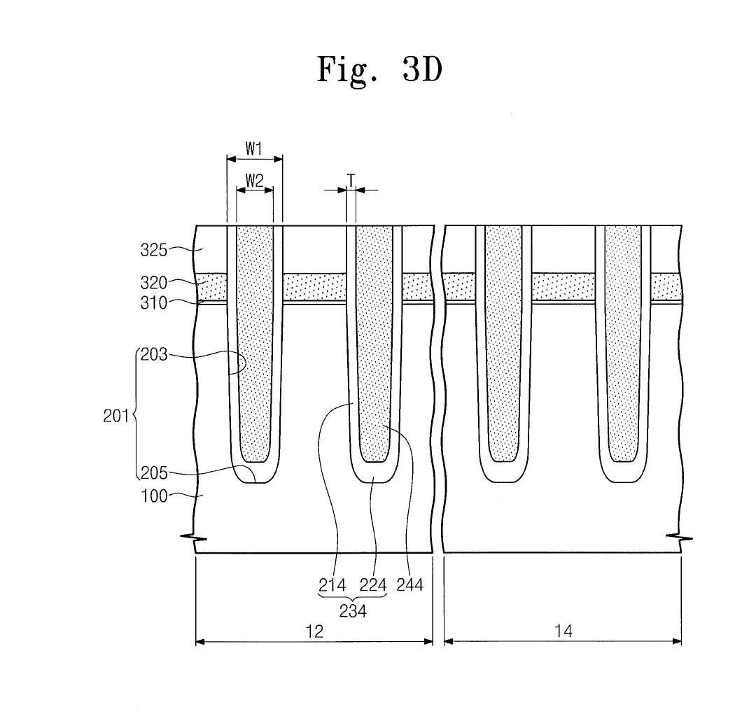

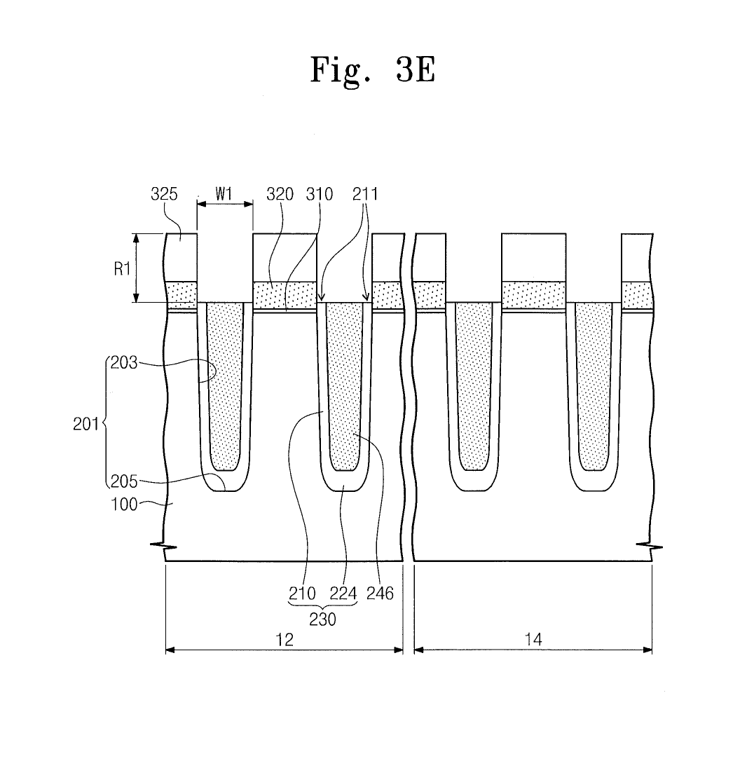

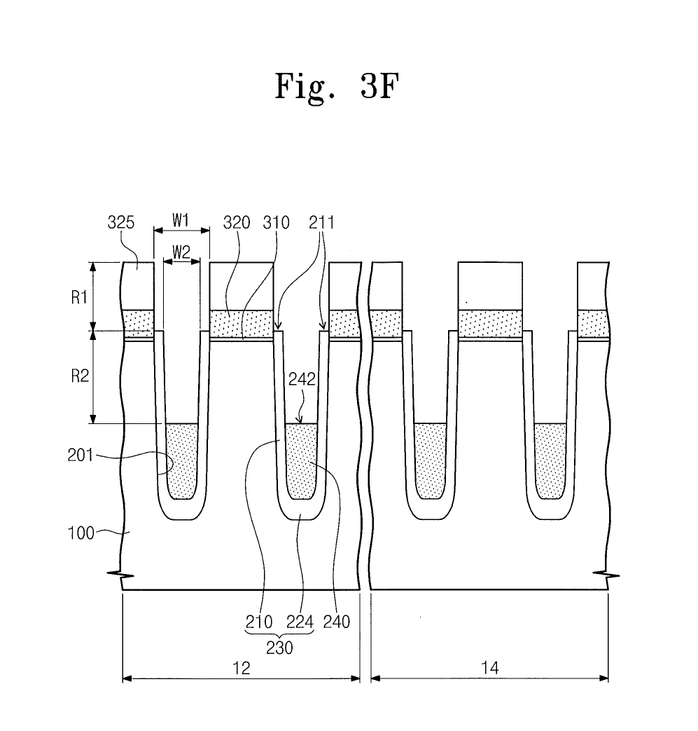

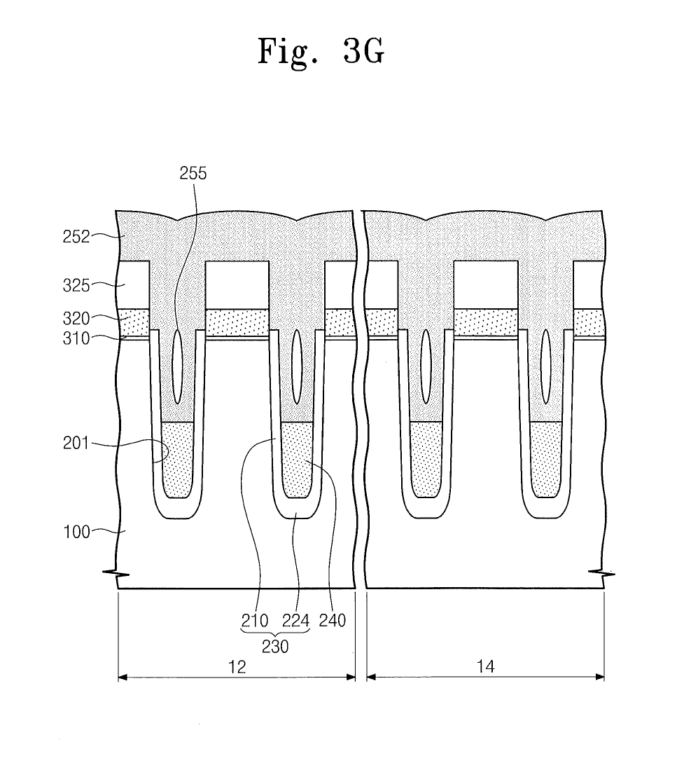

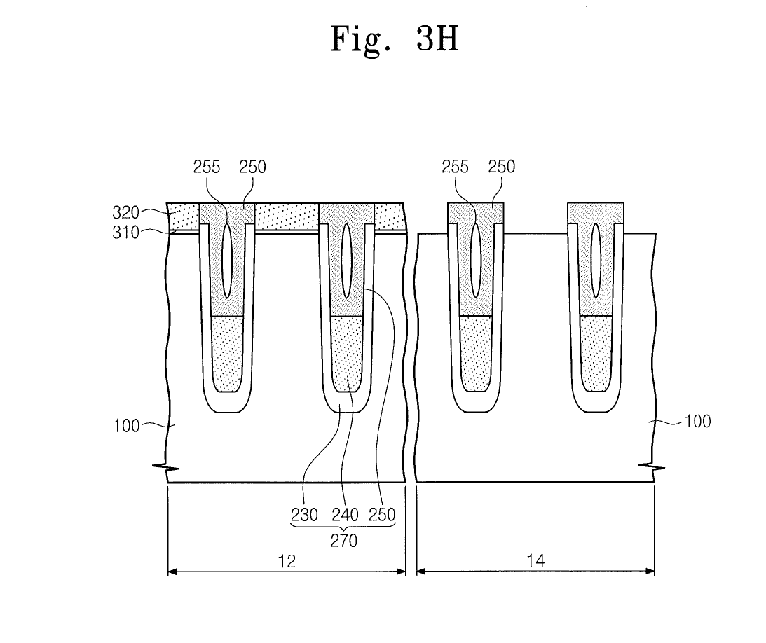

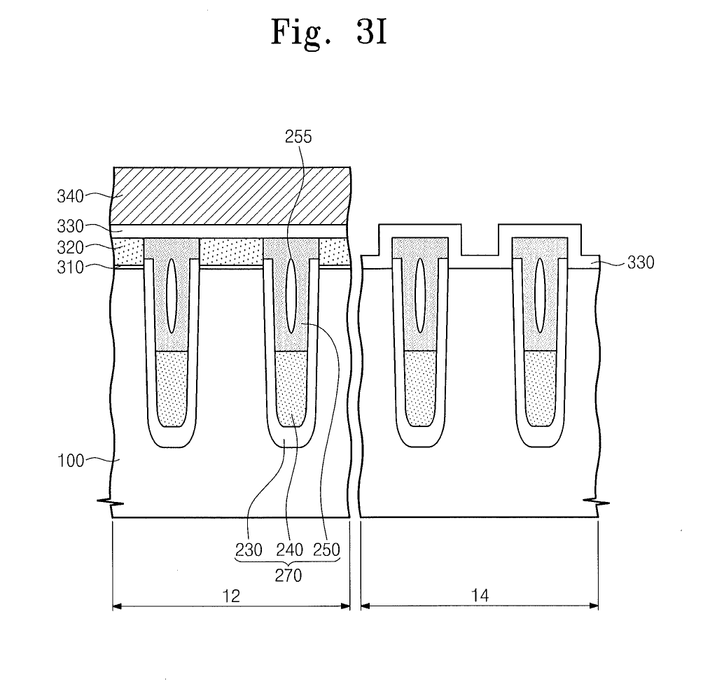

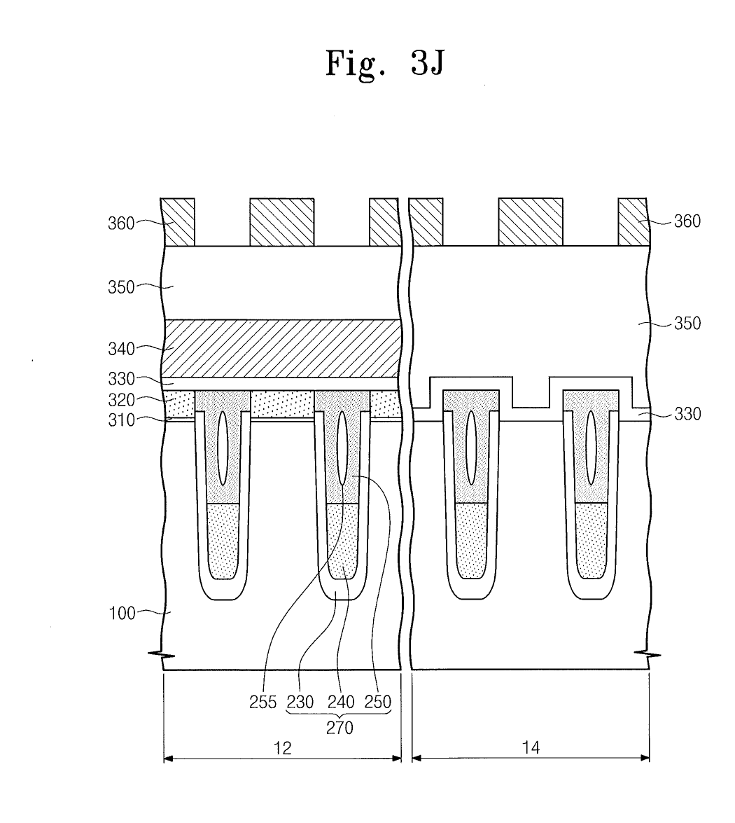

FIGS. 3A through 3J are cross-sectional views, which illustrate methods of fabricating a semiconductor device according to some exemplary embodiments. A first cross-sectional area 12 may be a cross-sectional area taken along the dotted line A-A′ in FIG. 1. A second cross-sectional area 14 may be a cross-sectional area taken along the dotted line B-B′ in FIG. 1.

Referring to FIGS. 1 and 3A, a substrate 100 including a first cross-sectional area 12 and a second cross-sectional area 14 may be provided. The substrate 100 may be, for instance, a silicon substrate. A tunnel insulating layer 310 and a charge storage layer 320 may be sequentially formed on the substrate 100. The tunnel insulating layer 310 may include thermal oxide. The charge storage layer 320 may be a charge trap layer or a floating gate. The charge trap layer may be formed of at least one selected from the group consisting of silicon nitride, nano crystalline silicon, nano crystalline silicon germanium, nano crystalline metal, aluminum oxide, hafnium oxide, hafnium aluminum oxide, and hafnium silicon oxynitride.

A mask layer 325 may be formed on the charge storage layer 320. The mask layer 325, as a patterned layer, may be formed to expose a predetermined area of the charge storage layer 320. The mask layer 325 may include, for instance, silicon nitride.

Referring to FIGS. 1 and 3B, a recess region 201 is formed to penetrate the mask layer 325, the charge storage layer 320, the tunnel insulating layer 310, and a portion of the substrate 100. For instance, using the mask layer 325 as an etching mask, the charge storage layer 320, the tunnel insulating layer 310, and part of the substrate 100 may be anisotropically etched to form the recess region 201. Various etching gases may be used perform an etching process according to etching targets.

The recess region 201 may be defined by inner surfaces, i.e., a side surface 203 and a bottom surface 205. The side surface 203 of the recess region 201 may include a side surface of the mask layer 325, a side surface of the tunnel insulating layer 310, and a side surface of a trench formed in the substrate 100. The side surface 203 of the recess region 201 may have a right angle or an obtuse angle. The bottom surface 205 of the recess region 201 may be a bottom surface of the trench. The distance between the side surfaces 203 in the recess region 201 may be a first width W1.

Referring to FIGS. 1 and 3C, a first dielectric layer 232 may be formed covering the recess region 201 along the inner surface of the recess region 201. The first dielectric layer 232 may be formed of a material having a lower dielectric constant than those of a second dielectric layer 242 and a third dielectric layer (252 in FIG. 3G), which will be formed in a subsequent process. The first dielectric layer 232 may be formed of for instance, middle temperature oxide. The first dielectric layer 232 may include a porous thin film, e.g., a silicon oxide film containing carbon and/or hydrogen.

The second dielectric layer 242 may be formed on the first dielectric pattern 232 to fill the recess region 201. The second dielectric layer 242 may be formed of a material having an etching selectivity with respect to the first dielectric layer 232, the charge storage layer 320, and the mask layer 325. The second dielectric layer 242 may include, for instance, a layer that is wet etched at least three times faster than the first dielectric layer 232. A wet-etching rate of the second dielectric layer 242 may be high at a narrow area. The second dielectric layer 242 may be formed of at least one selected from the group consisting of, for instance, Spin-On-Glass (SOG), Flowable-Oxide (FOX), Boron-Phosphorous Silicate Glass (BPSG), doped oxide such as germanium doped oxide, and combinations thereof.

Referring to FIGS. 1 and 3D, the second dielectric layer (242 in FIG. 3C) and the first dielectric layer (232 in FIG. 3C) are planarized down to a top surface of the mask layer 325 to form a planarized second dielectric layer 244 and a planarized first insulating layer 234. The planarization may be carried out by means of a chemical mechanical polishing (CMP) process.

According to the planarization process above, a top surface of the planarized second dielectric layer 244 and a top surface of a inner wall 214 of the planarized first dielectric layer 234 may be coplanar with the top surface of the mask layer 325. The planarized first dielectric layer 234 may comprise the inner wall 214 and a bottom portion 224. The bottom portion 224 may cover the bottom surface 205 of the recess region 201. The inner wall 214 may be connected to the bottom portion 224 and cover the recess region 201 along the side surface 203 of the recess region 201. Considering space for an air gap (255 in FIG. 3G), which may be formed subsequently, the thickness T of the inner wall 214 may be 35% or less of the first width W1 of the recess region 201. The distance between the inner walls 214 in the recess region may be defined as a second width W2.

To increase wet-etching selectivity of the planarized second dielectric layer 244, a heat treatment may be additionally carried out either after forming the second dielectric layer (242 in FIG. 3C) or after the planarization process. The heat treatment may include, for instance, an ultraviolet (UV) anneal process.

Referring to FIGS. 1 and 3E, a first region R1 having the first width W1 may be provided in the recess region 201 by first recessing the planarized second dielectric layer (244 of FIG. 3D) and the planarized first dielectric layer (235 of FIG. 3D) exposed between the mask layers 325. For instance, the side surface 203 of the recess region 201 may be exposed by anisotropic etching the planarized second dielectric layer (244 in FIG. 3D) and the inner wall 214 of the planarized first dielectric layer (234 of FIG. 3D) using the mask layer 325 as an etching mask. As a result, the first region R1 having the first width W1, which is a distance between the exposed side surfaces 203, may be provided in the recess region 201.

According to the first recess process, a first dielectric pattern 230 and a preliminary second dielectric patter 246 may be formed between the mask layers 325. The first recess process may be performed for the top surface 211 of the inner wall 210 of the first dielectric patter 230 to be located within a first range. The first range may be within a first distance or a second distance. The first distance may be a distance of equal to or less than 300 Å upward from the surface of the substrate 100. The second distance may be a distance of equal to or less than 500 Å downward from the surface of the substrate 100. The upward direction may be a direction extending towards the mask layer 325 from the substrate 100, and the downward direction may be a direction opposite to the upward direction. In order to protect the tunnel insulating layer 310, the first recess process may stop before the side surface of the tunnel insulating layer 310 is exposed.

Referring to FIGS. 1 and 3F, a second region R2 having about the second width W2 along at least a major portion thereof may be provided in the recess region 201 by second recessing the preliminary second dielectric pattern (246 in FIG. 3E) exposed between the inner walls 210 of the first dielectric pattern 230. For instance, a portion of a sidewall of the inner wall 210 of the first dielectric pattern 230 may be partially exposed by selectively wet etching the preliminary second dielectric pattern (246 in FIG. 3E). As a result, the second region R2 having the second width W2, which is a distance between opposite side surfaces of the exposed inner wall 210, may be provided in the recess region 201.

According to the second recess process, the preliminary second dielectric pattern (246 in FIG. 3E) may become second dielectric pattern 240. The second dielectric pattern 240 may cover the bottom portion 224 of the first dielectric pattern 230 and may be formed between-side surfaces of the lower portion of the inner wall 210. The second dielectric pattern 240 may have a planarized top surface. The second recess process may be performed until the top surface 242 of the second dielectric pattern 240 is positioned within the second range. The second range may be a distance equal to or less than 500 Å downward from the surface of the substrate 100.

Referring to FIGS. 1 and 3G, a third dielectric layer 252 having an air gap 255 may be formed by filling the recess region 201, which comprises the first region (R1 in FIG. 3F) and the second region (R2 in FIG. 3F), with an dielectric material. The third dielectric layer 252 may comprise, for instance, high-density plasma (HDP) oxide layer. The first region R1 is wider than the second region R2 in the recess region 201. Accordingly, when filling the recess region 201 with a dielectric material, an air gap 255 may be formed in the second region R2 due to the overhang at the entrance of the second region R2.

According to some embodiments, the location of the top surface 242 of the second dielectric patter 240 and the top surface 211 of the inner wall 210 of the first dielectric pattern may be adjusted. Accordingly, the location of the air gap 255 in the recess region 201 may be adjusted, and the air gap 255 may be uniformly formed. The air gap 255 may be formed between the active regions 110 neighboring the tunnel insulating layers 310 and may be completely enclosed by the third dielectric layer 252.

Referring to FIGS. 1 and 3H, the third dielectric layer (252 in FIG. 3G) and the mask layer (325 in FIG. 3F) may be planarized down to a top surface of the charge storage layer 320 to form a third dielectric pattern 250. The planarization process may be carried out by means of, for instance, a CMP process. A device isolation structure 270 may comprise the first dielectric pattern 230, the second dielectric pattern 240 and the third dielectric pattern 250. According to the planarization process, the top surface of the third dielectric pattern 250 may be coplanar with the top surface of the charge storage layer 320.

Following the planarization process, the substrate 100 between the device isolation structures 270 may be exposed by masking the first cross-sectional area 12 and selectively removing the charge storage layer 320 and the tunnel insulating layer 310 in the second cross-sectional area 14. The selective removal process may be, for instance, an anisotropic etching process.

Referring to FIGS. 1 and 3I, a blocking dielectric layer 330, which covers the third dielectric pattern 250 and the charge storage layer 320 in the first cross-sectional area 12 and the device isolation structure 270 and the exposed substrate 100 in the second cross-sectional area 14, may be formed. The blocking dielectric layer 330 may be uniformly formed by, for instance, chemical vapor deposition. The blocking dielectric layer 330 may be formed of a high-dielectric material such as SiO₂, SiN, SiON, HfO₂, ZrO₂, Al₂O3 or combinations thereof.

A control gate electrode 340 may be formed on the blocking dielectric layer 330 in the first cross-sectional area 12. For example, the control gate electrode 340 may be formed by providing a conductive layer on the blocking dielectric layers 330 in the first cross-sectional area 12 and the second cross-sectional area 14 and patterning the conductive layer. The patterning process may comprise an anisotropic etching process carried out to etch the conductive layer down to a top surface of the blocking dielectric layer 330 in the second cross-sectional area 14. The air gap 255 of the device isolation structure 260 in the second cross-sectional area 14 may be exposed due to overetching which may occur during the etching process. According to the one exemplary embodiment of the present inventive concept, the exposure of the air gap 255 may be prevented using the blocking dielectric layer 330 as an etch stop layer.

Referring to FIGS. 1 and 3J, an interlayer dielectric 350 may be formed to cover the control gate electrode 340 in the first cross-sectional area 12 and the blocking dielectric layer 330 in the second cross-sectional area 14. A bit line 360 may be formed on the interlayer dielectric 350.

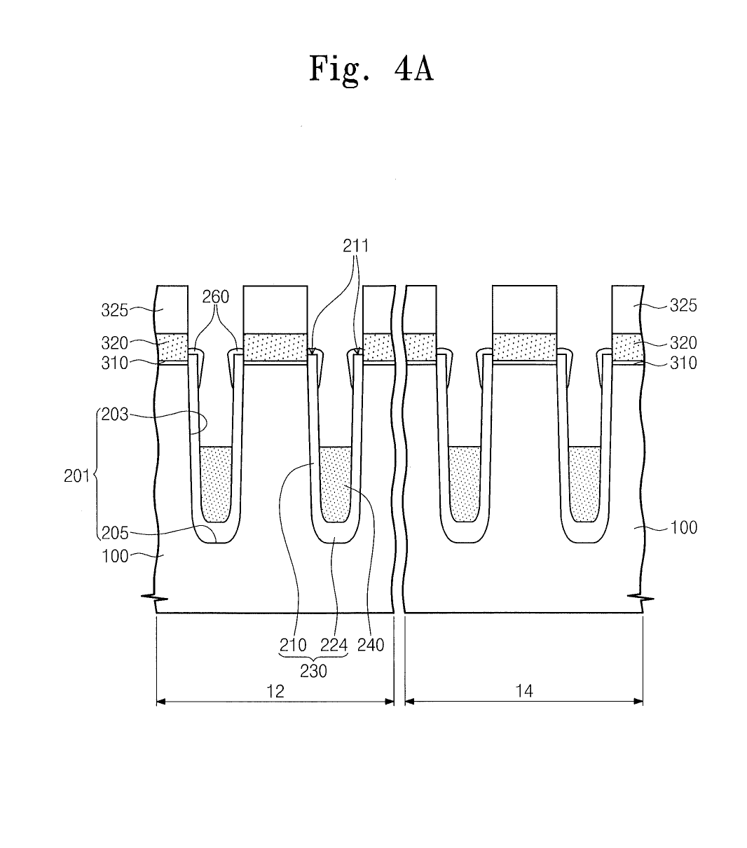

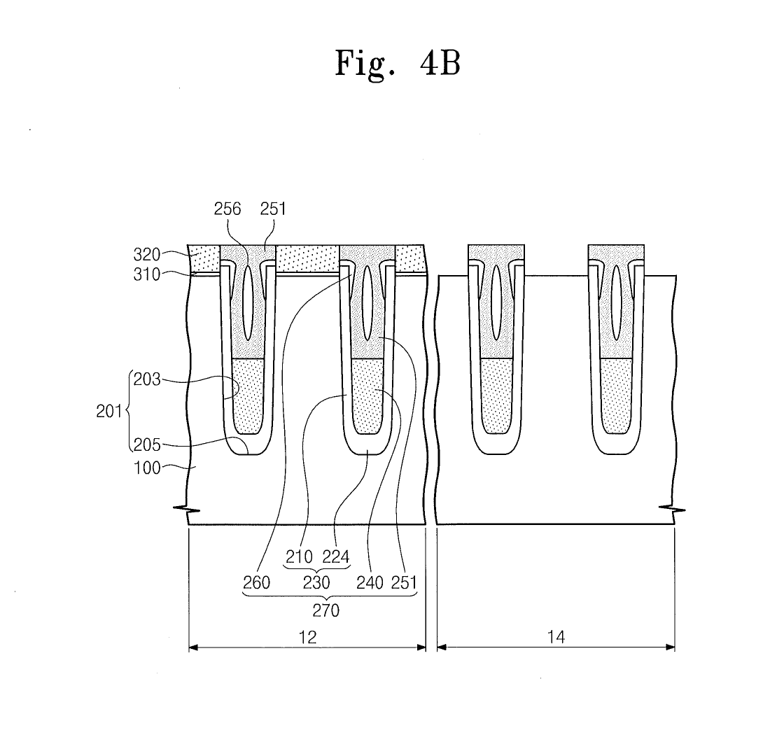

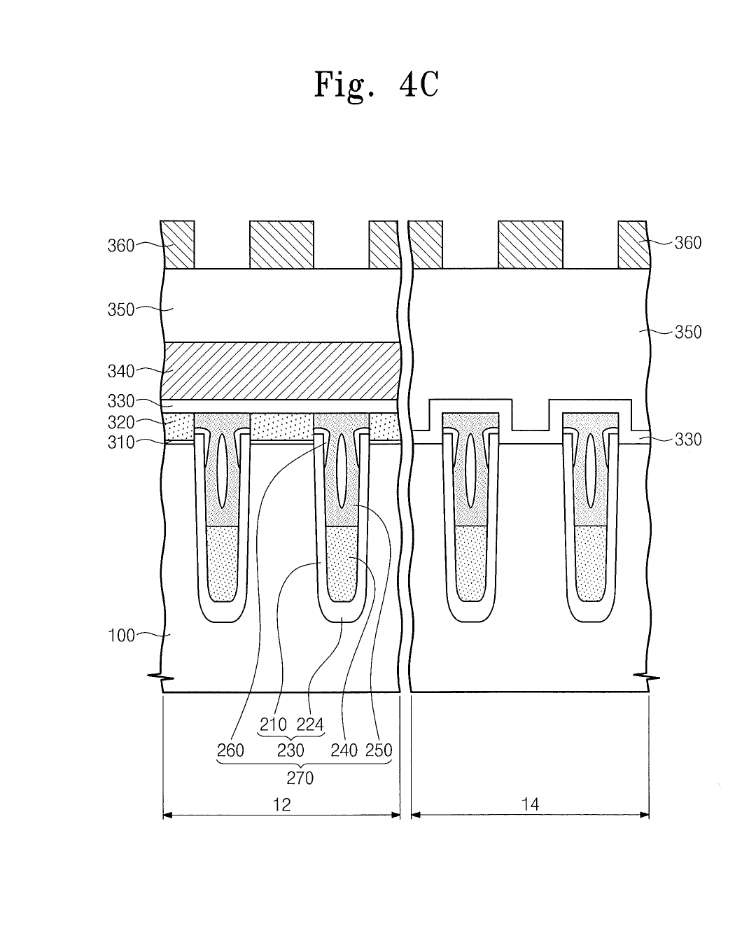

FIGS. 4A through 4C are cross-sectional views, which illustrate methods of fabricating a semiconductor device according to some other exemplary embodiments. For brevity of explanation, technical features that are the same or similar to those in previous embodiments will be briefly described or their description will be omitted below.

Referring to FIG. 4A, according to the method of manufacture depicted in FIGS. 1 and 3A though 3F, a second dielectric pattern 240 may be formed between inner walls 210 of a first dielectric pattern 230.

A fourth dielectric pattern 260 may be formed to cover the top surface 211 of the inner wall 210 of a first dielectric pattern 230 and a side surface connected and adjacent to the top surface 211. Residues (not shown) of the fourth dielectric pattern 260 may be formed on the second dielectric pattern 240. The fourth dielectric pattern 260 may be formed of a material having poorer step coverage than those of the first, the second, and the third dielectric patterns 230, 240, and 250. The fourth dielectric pattern 260 may be formed of, for instance, plasma enhanced oxide (PEOX).

Referring to FIG. 4B, an air gap 256 may be formed by filling the recess region 201 with dielectric materials. According to another embodiment of the present inventive concept, when the fourth dielectric patter 260 is formed at the boundary between the first region and the second region of the recess region 201 to fill the recess region 201 with a dielectric material, overhang may be increased at the entrance of the second region to facilitate the formation of the air gap 256.

After forming the air gap 256, the dielectric materials and the mask layers 325 may be planarized down to a top surface of the charge storage layer 320 to form a third dielectric pattern 251 in the first cross-sectional area 12 and the second-cross section area 14. A device isolation structure 271 according to another embodiment of the present inventive concept may include a first dielectric pattern 230, a second dielectric pattern 240, a third dielectric pattern 251 having an air gap 256, and a fourth dielectric pattern 260.

Following the planarization process, the substrate 100 between the device isolation structures 271 may be exposed by masking the first cross-sectional area 12 and selectively removing the charge storage layer (320 in FIG. 4A) and the tunnel insulating layer 310 in the second cross-sectional area 14. The selective removal process may be, for instance, an anisotropic etching process.

Referring to FIG. 4C, a blocking dielectric layer 330, a control gate electrode 340, an interlayer dielectric 350, and a bit line 360 may be formed according to the method depicted in FIGS. 1 and 3I though 3J.

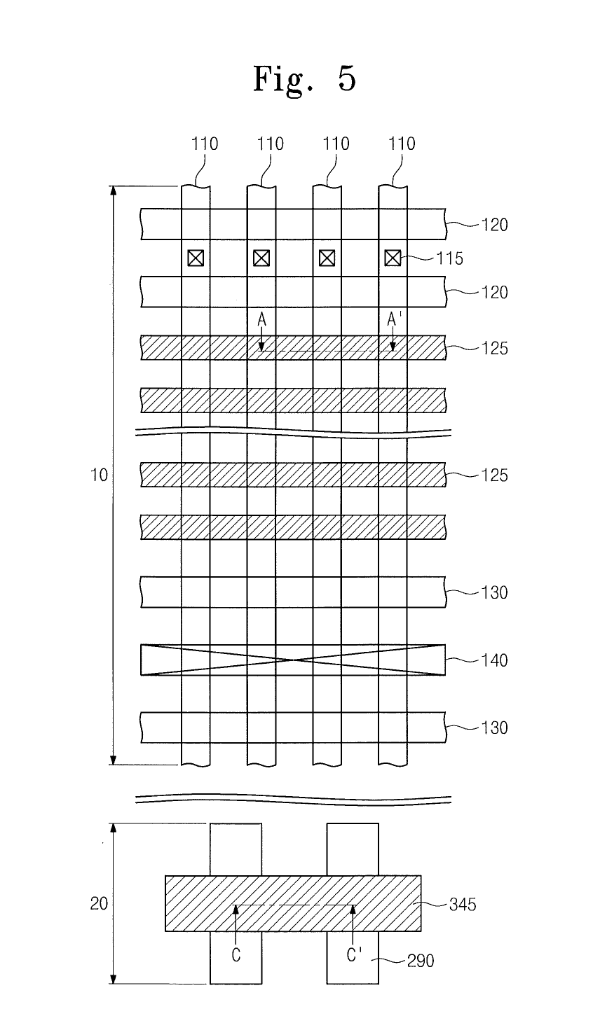

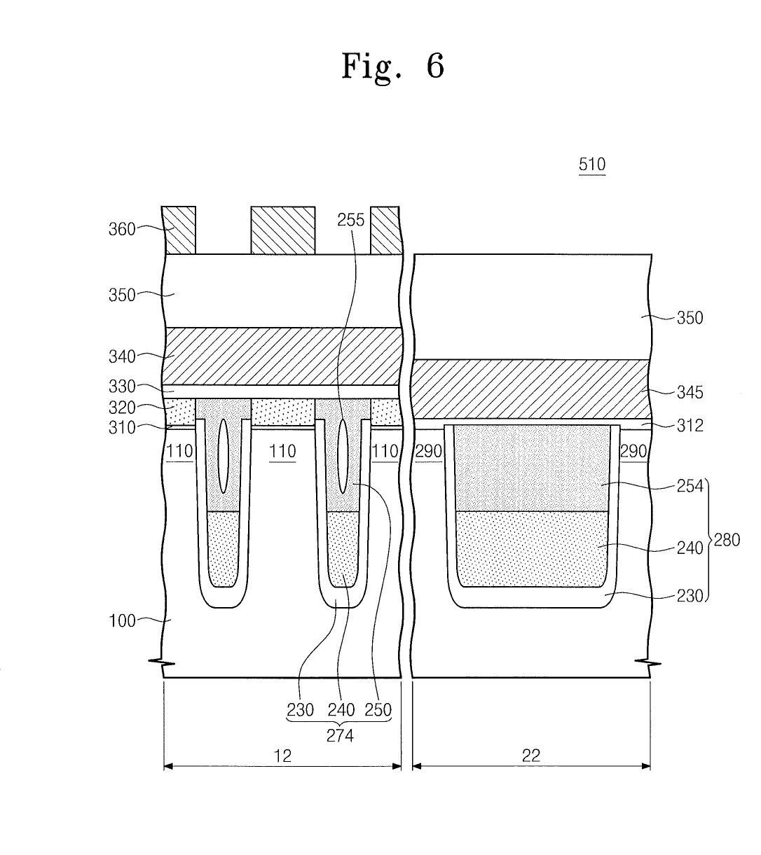

FIG. 5 is a top plan view showing a layout of a semiconductor device according to some modified exemplary embodiments. FIG. 6 is a cross-sectional view taken along the dotted lines A-A′ and C-C′ in FIG. 5 and illustrates a semiconductor device according to some modified exemplary embodiments. For brevity of explanation, some technical features that are the same as or similar to features that have been described above for previous embodiments will be briefly described or their description will be omitted. A first cross-sectional area 12 may be a cross-sectional area taken along the dotted line A-A′ in FIG. 5. A third cross-sectional area 22 may be a cross-sectional area taken along the dotted line C-C′ in FIG. 5.

Referring to FIGS. 5 and 6, a substrate 100 may include a cell region 10 and a peripheral circuit region 20. The cell region 10 may include a cell array including a plurality of cell strings. The plurality of cell strings may include a ground select line 130, a string select line 120, and a word lines 125 disposed between the ground select line 130 and the string select line 120. A common source line 140 may be provided between the ground select lines 130 adjacent to each other. The common source line 140 may electrically connect the source regions (not shown) of the ground select line 130. A bit line contact 115 may be provided between the string select lines 120 adjacent to each other. A bit line 360 may be disposed on the word line 125.

A device isolation structure 274 of the cell region 10 may define an active region 110 on the substrate. The device isolation structure 274 may comprise a first dielectric pattern 230, a second dielectric pattern 240, and a third dielectric pattern 250 having an air gap 255. A tunnel insulating layer 310 and a charge storage layer 320 may be sequentially stacked on the active region 110. A blocking dielectric layer 330 may be formed on the device isolation structure 274 and on the charge storage layer 320. The blocking dielectric layer 330 may uniformly cover the top surface of the device isolation structure 274 and the top surface of the charge storage structure 320. A control gate electrode 340 constituting a word line 125 may cover the blocking dielectric layer 330 of the first cross-sectional area 12. An interlayer dielectric 350 may cover the control gate electrode 340 of the first cross-sectional area 12. A bit line 360 may be disposed on the interlayer dielectric 350 of the first cross-sectional area 12.

The peripheral circuit region 20 may comprise a gate electrode 345, a gate dielectric 312 and a high-voltage and/or low-voltage transistors having source/drain regions (not shown) formed in a peripheral circuit active region 290 on both sides of the gate electrode 345. A peripheral circuit device isolation structure 280 may define the peripheral circuit active region 290 on the peripheral circuit region 20 on the substrate 100. A gate electrode 345 may be disposed on the peripheral circuit active region 290 with a gate dielectric 312 interposed therebetween. The gate electrode 345 may be disposed on the peripheral circuit device isolation structure 280 of the third cross-sectional area 22. The interlayer dielectric 350 may cover the gate electrode 345 of the third cross-sectional area 22.

The peripheral circuit device isolation structure 280 according to some modified exemplary embodiments, which is made of an identical or similar material to the device isolation structure 274 formed in the cell region 10, may comprise a first dielectric pattern 230, a second dielectric pattern 240, and a peripheral third dielectric pattern 254 in the third cross-sectional area 22. The peripheral third dielectric pattern 254 may include an identical or similar material to the third dielectric pattern 250 in the cell region 10. According to these modified exemplary embodiments, a semiconductor device 510 may be provided with the device isolation structure 274 and the peripheral circuit device isolation structure 280.

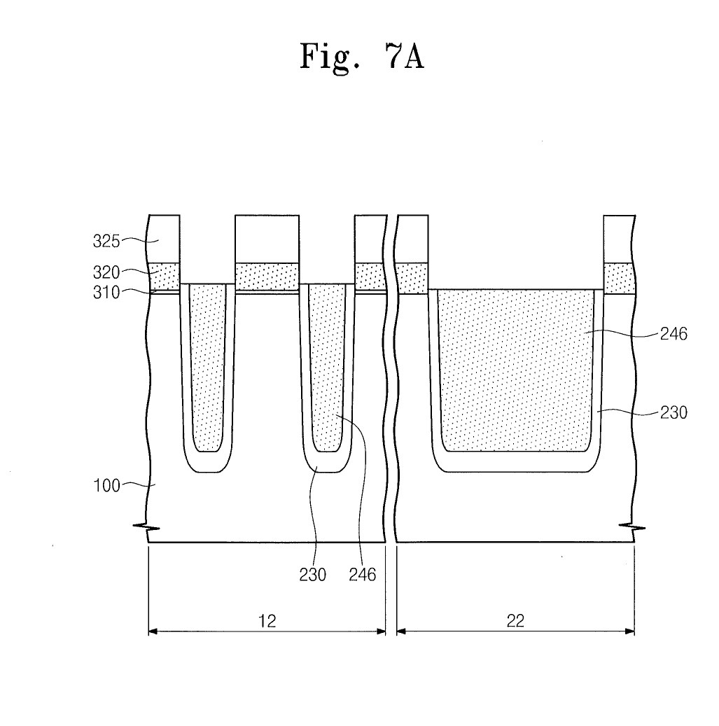

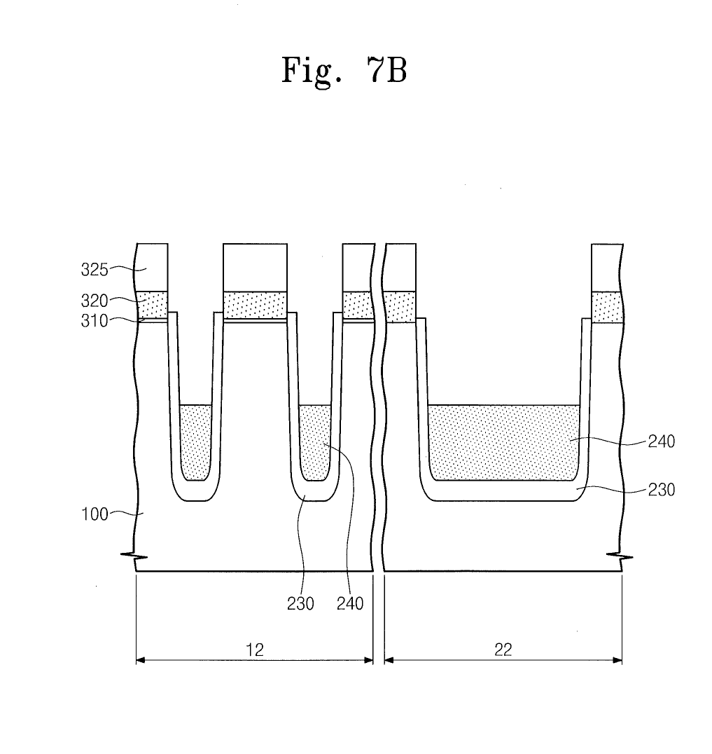

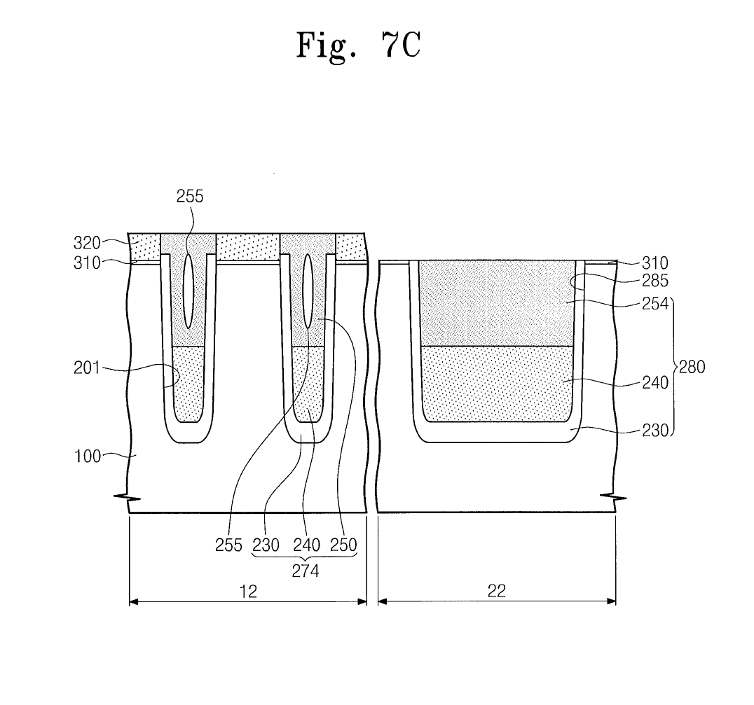

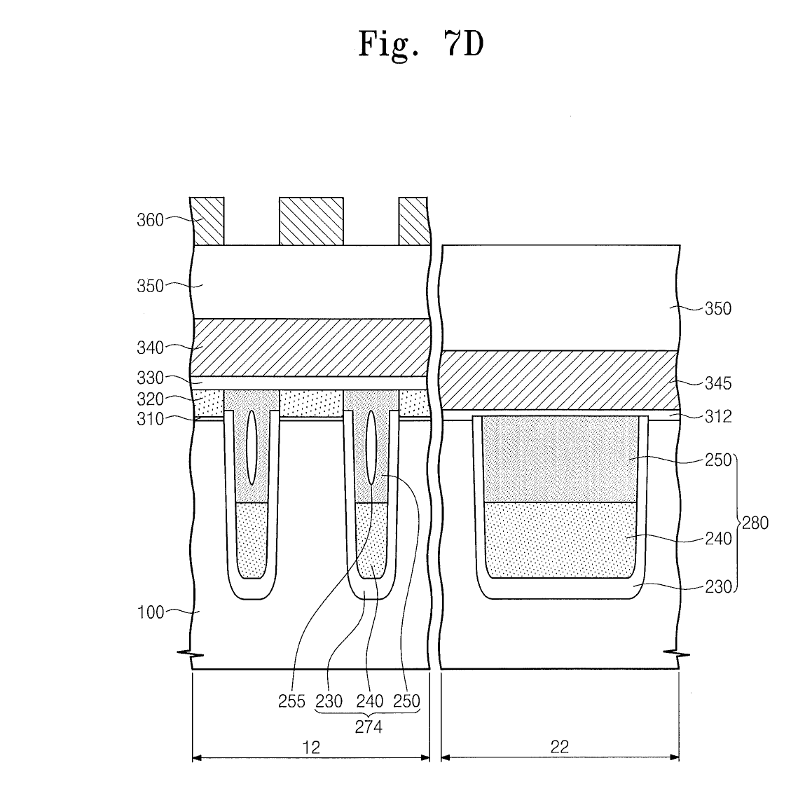

FIGS. 7A through 7D are cross-sectional views, which illustrate methods of fabricating a semiconductor device according to some other modified exemplary embodiments. These modified embodiments are similar to the previous modified embodiments. Therefore, duplicate technical features will be briefly explained or not be explained for the brevity of the description.

Referring to FIG. 7A, a first dielectric pattern 230 and a preliminary second dielectric pattern 246 may be formed between mask layers 325 in the first cross-sectional area 12 by performing a first recess process in the same manner as described in FIGS. 1 and 3E.

According to the first recess process, a first dielectric pattern 230 and a preliminary second dielectric pattern 246 may be formed between mask layers 325 in the third cross-sectional area 22.

Referring to FIG. 7B, a second dielectric pattern 240 may be formed between the inner walls of the first dielectric pattern 230 by second recess process selectively recessing the preliminary second dielectric pattern (246 in FIG. 7A) of the first cross-sectional area 12.

According to the second recess process, a second dielectric pattern 240 may be formed between the inner walls of the first dielectric pattern 230 of the third cross-sectional area 22.

According to FIG. 7C, an air gap 255 may be formed by filling the recess region 201 of the first cross-sectional area 12 with dielectric materials. The dielectric materials may fill a peripheral circuit trench 285. Because width of the peripheral circuit trench 285 is greater than that of the recess region 201, the air gap 255 may not be formed in the peripheral circuit trench 285.

After forming the air gap 255, a third dielectric pattern 250 may be formed between the charge storage layers 320 in the first cross-sectional area 12 by planarizing the dielectric materials and the mask layers 325 down to a top surface of the charger storage layer 320. The device isolation structure 274 of the first cross-sectional area 12 may comprise the first dielectric pattern 230, the second dielectric pattern 240, and the third dielectric pattern 250 containing the air gap 255. The planarization process may form a preliminary third dielectric pattern between charge storage layers (320 in FIG. 7B) of the third cross-sectional area 22.

After completing the planarization process, a peripheral third dielectric pattern 254 may be formed by masking the third dielectric pattern 250 and the charge storage layer 320 of the first cross-sectional area 12 and planarizing the preliminary third dielectric pattern and the charge storage layer (320 in FIG. 7B) in the third cross-sectional area 22 until the tunnel insulating layer 310 is exposed. A peripheral circuit isolation structure 280 may comprise the first dielectric pattern 230, the second dielectric pattern 240 and the peripheral third dielectric pattern 254 of the third cross-sectional area 22. The tunnel insulating layer 310 of the third cross-sectional area 22 may be removed.

Referring to FIG. 7D, a blocking dielectric layer 330 and a control gate electrode 340 may be sequentially formed on the device isolation structure 270 and the charge storage layer 320 of the first cross-sectional area 12. An interlayer dielectric 350 and a bit line 360 may be sequentially formed on the control gate electrode 340.

A gate dielectric 312 and a gate electrode 345 may be sequentially formed on the peripheral circuit active area 290 and the peripheral circuit device isolation structure 280 of the third cross-sectional area 22. The interlayer dielectric 350 may be formed on the gate electrode 345. The gate dielectric 312 may be formed of the same or similar material to the blocking dielectric layer 330. The gate electrode 345 may be formed of the same or similar material to the control gate electrode 340.

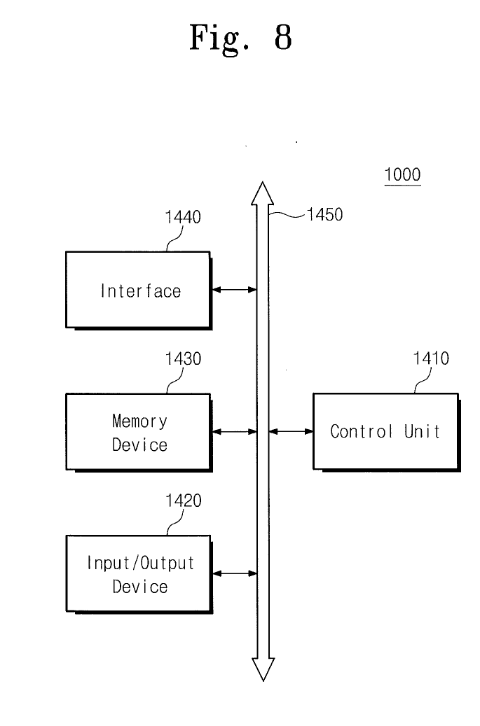

FIG. 8 is a block diagram, which illustrates an electronic system employing a semiconductor device according to some exemplary embodiments of the present inventive concept.

Referring to FIG. 8, the electronic system 1000 employing a semiconductor device may comprise a control unit 1410, an input/output device 1420, and a memory device 1430. The control unit 1410, the input/output device 1420, and the memory device 1430 may be coupled to each other through a bus 1450. The bus 1450 may function as a path along which data and/or operation signal are transmitted. The control unit 1410 may include at least one selected from the group consisting of a microprocessor, a digital signal processor, a microcontroller, and logic devices capable of performing similar functions. The input/output device 1420 may include at least one selected from the group consisting of a keypad, a keyboard, and a display device. The memory device 1430 may be a data storage. The memory device 1430 may store data and/or instructions executed by the control unit 1410. The memory device 1430 may include the semiconductor memory devices 500, 501, and 510 according to some exemplary embodiments explained above. The electronic system 1000 may comprise an interface 1440 configured to transmit/receive data to/from a communication network. The interface 1440 may be a wired or wireless interface. For instance, the interface 1440 may include an antenna or wireless/cable transceiver.

The electronic system 1000 may be implemented in various forms such as a mobile system, personal computer, industrial computer, or various multi-functional systems. For instance, the mobile system may be a personal digital assistant (PDA), portable computer, web tablet, mobile phone, wireless phone, laptop computer, memory card, digital music system, data transmission/reception system, etc. In the case that the electronic system 1000 is equipment performing wireless communication, the electronic system 1000 can be employed in communication interface protocol such as the third generation communication systems like CDMA, GSM, NADC, E-TDMA, WCDMA, CDMA2000.

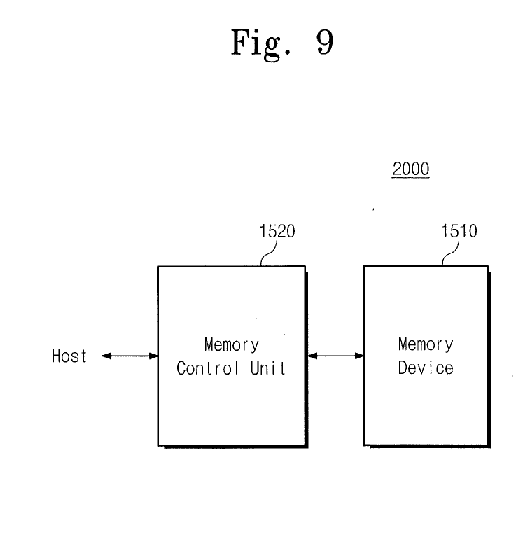

FIG. 9 is a block diagram, which illustrates of a memory card employing a semiconductor device according to some exemplary embodiments of the present inventive concept.

Referring to FIG. 9, the memory card 2000 according to some exemplary embodiments of the present inventive concept may comprise a memory device 1510 and a memory control unit 1520. The memory device 1510 may store data. It is desirable for the memory device 1510 to have a non-volatile characteristic, i.e. to retain information, even when power is removed. The memory device 1510 may comprise semiconductor memory devices 500, 501, 510 according to some exemplary embodiments or some modified embodiments of the present inventive concept explained above. The memory control unit 1520 may read data from or write date into the memory device 1510 in response to a host's read/write request.

The semiconductor memory devices 500, 501, 510 according to exemplary embodiments of the present inventive concept may be mounted in various forms of packages. For instance, the semiconductor memory devices 500, 501, 510 may be packaged using various packaging technologies such as Package on Package, Ball Grid Arrays, Chip scale packages, Plastic Leaded Chip Carrier, Plastic Dual In-Line Package, Multi Chip Package, Wafer Level Package, Wafer Level Fabricated Package, Wafer Level Processed Stack Package, Die On Waffle Package, Die in Wafer Form, Chip On Board, Ceramic Dual In-Line Package, Plastic Metric Quad Flat Pack, Thin Quad Flat Pack, Small Outline Package, Shrink Small Outline Package, Thin Small Outline Package, Thin Quad Flat Package, and System In Package.

As described above for some exemplary embodiments of the present inventive concept, channel coupling may be decreased and maybe without degrading uniformity of the device isolation structure. It is therefore possible to improve channel boosting efficiency during a program operation and to provide a semiconductor device having an improved channel voltage distribution during the boosting operation.

The foregoing is illustrative of various example embodiments and is not to be construed as limited to the specific example embodiments disclosed. Although some example embodiments have been described, those skilled in the art will readily appreciate that many modifications are possible in the example embodiments without materially departing from the novel teachings and advantages of the present invention. Accordingly, all such modifications are intended to be included within the scope of the present inventive concept as defined in the claims.

What is claimed is:

1. A semiconductor device, comprising:
a tunnel insulating layer and a charge storage layer sequentially stacked on a substrate;
a recess region penetrating the charge storage layer, the tunnel insulating layer and a portion of the substrate, being defined by a bottom surface and a side surface extending from the bottom surface;
a first dielectric pattern including a bottom portion covering the bottom surface and inner walls extending from the bottom portion and covering a portion of the side surface of the recess region; and
a second dielectric pattern in the recess region between the inner walls of the first dielectric pattern, the second dielectric pattern enclosing an air gap within the second dielectric pattern.

2. The semiconductor device of claim 1, wherein the air gap that is enclosed by the second dielectric pattern extends through a major portion of the second dielectric pattern in a direction away from the bottom surface of the recess region.

3. The semiconductor device of claim 2, wherein the air gap that is enclosed by the second dielectric pattern extends through a central portion of the second dielectric pattern.

4. The semiconductor device of claim 1, wherein the air gap that is enclosed by the second dielectric pattern extends along at least one third of a length of the recess region.

5. The semiconductor device of claim 1, further comprising:
a third dielectric pattern that is between the bottom portion of the first dielectric pattern and the second dielectric pattern, the third dielectric pattern being disposed between the inner walls of the first dielectric pattern,
wherein the first, the second, and the third dielectric pattern fill the recess region to form a device isolation structure defining an active region on the substrate.

6. The semiconductor device of claim 5, wherein a top surface of the first dielectric pattern directly contacts the second dielectric pattern in the recess region, and the inner wall of the first dielectric pattern directly contacts the second and the third dielectric patterns.

7. The semiconductor device of claim 6:
wherein the recess region is defined by a first region having a first width, and a second region having a second width that corresponds to a distance between the inner sidewalls of the first dielectric pattern, the second width is smaller than the first width; wherein the first region is defined by a region between the top surface of the inner wall of the first dielectric pattern and a top surface of the second dielectric pattern, and the second region is defined by a region between the top surface of the inner wall of the first dielectric pattern and a top surface of the third dielectric pattern.

8. The semiconductor device of claim 6, wherein the air gap enclosed by the second dielectric pattern is confined within the second region between adjacent portions of the tunnel insulating layer that are separated by the recess region.

9. The semiconductor device of claim 6, wherein the inner wall of the first dielectric pattern covers side surfaces of the tunnel insulating layer that are separated by the recess region.

10. The semiconductor device of claim 6, wherein the first dielectric pattern has a lower dielectric constant than the second and the third dielectric patterns.

11. The semiconductor device of claim 6, wherein the charge storage layer comprises a charge trap layer.

12. The semiconductor device of claim 6, further comprising:
a fourth dielectric pattern that covers the top surface and an upper portion of the inner wall of the first dielectric pattern and narrows a width of an upper portion of the recess region to cause formation of the air gap during formation of the second dielectric pattern.

13. The semiconductor device of claim 12, wherein the fourth dielectric pattern comprises a material having poorer step coverage than the first, the second, and the third dielectric patterns.

14. The semiconductor device of claim 12, wherein the fourth dielectric pattern extends an equal distance away from the upper portion of the inner wall of the first dielectric pattern to narrow the width of an upper portion of the recess region.

15. The semiconductor device of claim 12, wherein the air gap within the second dielectric pattern is between portions of the fourth dielectric pattern and extends downward through a major portion of the second dielectric pattern.

16. The semiconductor device of claim 15, wherein the air gap within the second dielectric pattern is about equal distance from the portions of the fourth dielectric pattern between which it extends.

17. The semiconductor device of claim 16, wherein a top surface of the air gap within the second dielectric pattern is below a top surface of the fourth dielectric pattern and between portions of the fourth dielectric pattern.

18. The semiconductor device of claim 1, further comprising:
a plurality of the recess regions with the first and second dielectric patterns residing therein, wherein each of the second dielectric patterns encloses a substantially similar size air gap within that second dielectric pattern.
